(19) United States
(12) Patent Application Publication
(10) Pub. No.: US 2018/0337297 A1
(43) Pub. Date: Nov. 22, 2018

(54) SOLAR CELL MODULE

(71) Applicant: Mitsui Chemicals Tohcello, Inc., Chiyoda-ku, Tokyo (JP)

(72) Inventors: Takanobu MUROFUSHI, Nagoya-shi, Aichi (JP); Jun TOKUHIRO, Shinagawa-ku, Tokyo (JP)

(73) Assignee: Mitsui Chemicals Tohcello, Inc., Chiyoda-ku, Tokyo (JP)

(21) Appl. No.: 15/776,484

(22) PCT Filed: Nov. 18, 2016
(86) PCT No.: PCT/JP2016/084233

§ 371 Date: May 16, 2018

(30) Foreign Application Priority Data
Nov. 25, 2015 (JP) 2015-229758

(51) Int. Cl. H01L 31/048; H01L 31/0224; H01B 3/44

(52) U.S. Cl. CPC H01L 31/0481; H01B 3/441; H01L 31/022425; H01L 31/0488

(57) ABSTRACT

A solar cell module includes a light-receiving surface-side protective member, a rear surface-side protective member, solar cell elements, and an encapsulating layer that encapsulates the solar cell elements between the light-receiving surface-side protective member and the rear surface-side protective member. The light-receiving surface-side protective member has a plurality of fine recess portions and a plurality of fine protrusion portions on at least a solar cell element side surface, busbar electrodes are provided to the solar cell elements on at least a light-receiving surface-side surface. The encapsulating layer has a light-receiving surface side-encapsulating layer having an effective thickness of 0.01 mm to less than 0.25 mm and a rear surface-side encapsulating layer, and the solar cell elements are encapsulated between the light-receiving surface side-encapsulating layer and the rear surface-side encapsulating layer. A solar cell-encapsulating material configuring the light-receiving surface side-encapsulating layer has a defined elastic modulus at 23° C.

### TECHNICAL FIELD

The present invention relates to a solar cell module.

### BACKGROUND ART

Global environmental problems, energy problems, and the like become more serious, and thus a solar cell attracts attention as energy generation means that is clean and has no concern about exhaustion. In a case where a solar cell is used outside, for example, in the roof of a building, the solar cell is generally used in a form of solar cell modules.

Generally, the solar cell module is manufactured through the following procedure. First, a light-receiving surface-side protective member, a solar cell-encapsulating material, a solar cell element, a solar cell-encapsulating material, and a rear surface-side protective member are sequentially laminated. After that, a lamination method or the like in which the above-described components are vacuum-suctioned so as to be heated and compressed is used, thereby manufacturing the solar cell module. The solar cell module manufactured as described above has weather resistance and also becomes suitable for outdoor use, for example, in the roof of a building.

Examples of the solar cell-encapsulating material include the solar cell-encapsulating materials described in Patent Documents 1 to 3. Patent Document 1 describes an ethylene vinyl acetate copolymer film as a solar cell-encapsulating film. Patent Document 2 describes a solar cell-encapsulating material made of an α-olefin-based copolymer. Patent Document 3 describes a resin composition for a solar cell-encapsulating material containing an ethylene.α-olefin copolymer.

### RELATED DOCUMENT

### Patent Document

[Patent Document 1] Japanese Laid-open Patent Publication No. 2010-53298

[Patent Document 2] Japanese Laid-open Patent Publication No. 2006-210906

[Patent Document 3] Japanese Laid-open Patent Publication No. 2010-258439

### SUMMARY OF THE INVENTION

### Technical Problem

In solar cell modules, the thickness reduction of solar cell-encapsulating materials is attempted from the viewpoint of obtaining a high solar power generation amount by ensuring a sufficient light transmittance.

However, according to the present inventors' studies, it was clarified that, in solar cell modules of the related art, when the thickness of the solar cell-encapsulating material is reduced, during the production of solar cell modules or the repetitive use in environments in which temperatures significantly change, solar cell elements or wires are damaged by stress, and the output reduction of the solar cell modules is likely to be caused.

The present invention has been made in consideration of the above-described circumstances and provides a solar cell module in which the output reduction of the solar cell module is suppressed and the thickness of an encapsulating layer is thin.

### Solution to Problem

The present inventors performed intensive studies in order to provide a solar cell module in which the output reduction of the solar cell module is suppressed and the thickness of an encapsulating layer is thin. As a result, the present inventors found that, when the thickness of an encapsulating layer on a busbar electrode and the elastic modulus of a solar cell-encapsulating material configuring the encapsulating layer are controlled in specific ranges, it is possible to reduce the thickness of the encapsulating layer while suppressing damage to solar cell elements or wires, and completed the present invention.

According to the present invention, solar cell modules described below are provided.

[1] A solar cell module including: a light-receiving surface-side protective member; a rear surface-side protective member; a solar cell element; and an encapsulating layer that encapsulates the solar cell element between the light-receiving surface-side protective member and the rear surface-side protective member, in which the light-receiving surface-side protective member has a plurality of fine recess portions and a plurality of fine protrusion portions on at least the solar cell element-side surface, a busbar electrode is provided to the solar cell element on at least a light-receiving surface-side surface, the encapsulating layer has a light-receiving surface side-encapsulating layer provided between the light-receiving surface-side protective member and the solar cell element and a rear surface-side encapsulating layer provided between the rear surface-side protective member and the solar cell element, the solar cell element is encapsulated between the light-receiving surface side-encapsulating layer and the rear surface-side encapsulating layer, the light-receiving surface side-encapsulating layer includes at least one type of resin selected from a polyolefin-based resin and an ethylene.polar monomer copolymer, an elastic modulus at 23° C. of a solar cell-encapsulating material configuring the light-receiving surface side-encapsulating layer is equal to or greater than 5 MPa and equal to or smaller than 30 MPa, and, when an average thickness of the light-receiving surface side-encapsulating layer is represented by X [mm], an average thickness of the busbar electrode on the light-receiving surface side is represented by Y [mm], and a depth of the recess portion is represented by Z [mm], an effective thickness of the light-receiving surface side-encapsulating layer represented by (X-Y-Z) is equal to or greater than 0.01 mm and smaller than 0.25 mm.

[2] The solar cell module according to [1], in which the average thickness (Y) of the busbar electrode is equal to or greater than 0.02 mm and equal to or smaller than 0.6 mm.

[3] The solar cell module according to [1] or [2], in which the depth (Z) of the recess portion is equal to or greater than 0.02 mm and equal to or smaller than 0.5 mm.

[4] The solar cell module according to any one of [1] to [3], in which the resin included in the light-receiving surface side-encapsulating layer includes an ethylene.α-olefin copolymer.

[5] The solar cell module according to any one of [1] to [4], in which the average thickness of the solar cell element is equal to or greater than 0.01 mm and equal to or smaller than 0.5 mm.

[6] The solar cell module according to any one of [1] to [5], in which the average thickness (X) of the light-receiving surface side-encapsulating layer is equal to or smaller than 0.60 mm.

[7] The solar cell module according to any one of [1] to [6], in which the solar cell-encapsulating material configuring the light-receiving surface side-encapsulating layer further includes a lubricant.

### Advantageous Effects of Invention

According to the present invention, it is possible to realize a solar cell module in which the output reduction of the solar cell module is suppressed and the thickness of an encapsulating layer is thin.

### BRIEF DESCRIPTION OF THE DRAWINGS

The object and other objects, features and advantages which are described above are clarified by a preferred embodiment which will be described below, and the following accompanying drawings.

FIG. 1 is a schematic cross-sectional view illustrating an embodiment of a solar cell module according to the present invention.

FIG. 2 is a schematic plan view illustrating one configuration example of a light-receiving surface and a rear surface of a solar cell element.

### DESCRIPTION OF EMBODIMENTS

Hereinafter, an embodiment of the present invention will be described using drawings. Furthermore, in all of the drawings, the same component will be denoted by the same reference sign, and description thereof will be not repeated. In addition, a numerical range of “A to B” indicates equal to or greater than A and equal to or smaller than B unless particularly otherwise described.

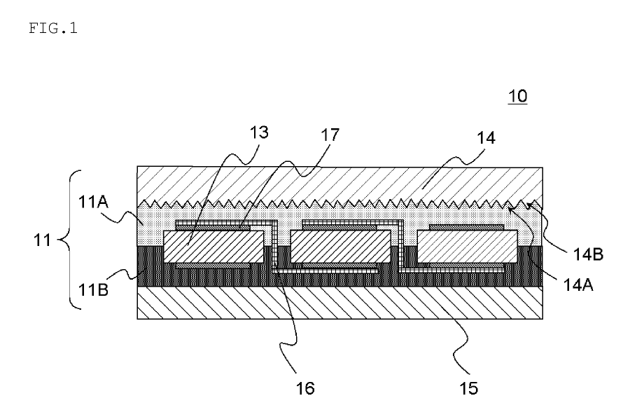

FIG. 1 is a schematic cross-sectional view illustrating an embodiment of a solar cell module of the present invention. A solar cell module 10 illustrated in FIG. 1 includes a light-receiving surface-side protective member 14, a rear surface-side protective member 15, solar cell elements 13, and an encapsulating layer 11 that encapsulates the solar cell elements 13 between the light-receiving surface-side protective member 14 and the rear surface-side protective member 15.

The light-receiving surface-side protective member 14 has a plurality of fine recess portions 14A and a plurality of fine protrusion portions 14B on at least the solar cell element 13-side surface, and busbar electrodes 17 are provided to the solar cell elements 13 on at least a light-receiving surface-side surface. The encapsulating layer 11 has a light-receiving surface side-encapsulating layer 11A provided between the light-receiving surface-side protective member 14 and the solar cell elements 13 and a rear surface-side encapsulating layer 11B provided between the rear surface-side protective member 15 and the solar cell elements 13, the solar cell elements 13 are encapsulated between the light-receiving surface side-encapsulating layer 11A and the rear surface-side encapsulating layer 11B. The light-receiving surface side-encapsulating layer 11A includes at least one type of resin selected from a polyolefin-based resin and an ethylene.polar monomer copolymer (hereinafter, also referred to as the resin (P)).

The elastic modulus at 23° C. of a solar cell-encapsulating material configuring the light-receiving surface side-encapsulating layer 11A is equal to or greater than 5 MPa and equal to or smaller than 30 MPa, preferably equal to or greater than 6 MPa and equal to or smaller than 28 MPa, more preferably equal to or greater than 6 MPa and equal to or smaller than 25 MPa, and particularly preferably equal to or greater than 8 MPa and equal to or smaller than 15 MPa.

When the average thickness of the light-receiving surface side-encapsulating layer 11A is represented by X [mm], the average thickness of the busbar electrode 17 on the light-receiving surface side is represented by Y [mm], and the depth of the recess portion 14A is represented by Z [mm], the lower limit of the effective thickness of the light-receiving surface side-encapsulating layer 11A represented by (X-Y-Z) is equal to or greater than 0.01 mm, preferably equal to or greater than 0.02 mm, more preferably equal to or greater than 0.05 mm, still more preferably equal to or greater than 0.07 mm, and particularly preferably equal to or greater than 0.08 mm. In addition, the upper limit of the effective thickness of the light-receiving surface side-encapsulating layer 11A represented by (X-Y-Z) is smaller than 0.25 mm, preferably equal to or smaller than 0.20 mm, more preferably smaller than 0.20 mm, still more preferably equal to or smaller than 0.18 mm, and particularly preferably equal to or smaller than 0.15 mm.

When the effective thickness of the light-receiving surface side-encapsulating layer 11A is set to equal to or greater than the lower limit value, during the production of the solar cell module or the repetitive use in environments in which temperatures significantly change, it is possible to suppress the occurrence of damage to the solar cell elements or wires due to stress, and consequently it is possible to suppress the reduction of the output of the solar cell module.

In addition, when the effective thickness of the light-receiving surface side-encapsulating layer 11A is set to be less than the upper limit value or equal to or smaller than the upper limit value, it is possible to realize the thickness reduction of the encapsulating layer, and consequently, it is possible to obtain the solar cell module having a thinner thickness while maintaining the output even after temperature cycles.

The average thickness (X) of the light-receiving surface side-encapsulating layer 11A can be computed from X=W₁/(D₁×10) using the weight W₁ (g/100 cm²) of a 10 cm×10 cm-sized specimen of the light-receiving surface side-encapsulating layer 11A and the density D₁ (g/cm³) of the light-receiving surface side-encapsulating layer 11A.

The average thickness (X) of the light-receiving surface side-encapsulating layer 11A is preferably equal to or smaller than 0.60 mm from the viewpoint of the size reduction of the module. The average thickness is preferably in a range of 0.40 to 0.60 mm and more preferably in a range of 0.43 to 0.55 mm from the viewpoint of handling.

The lower limit of the elastic modulus at 23° C. of the solar cell-encapsulating material configuring the light-receiving surface side-encapsulating layer 11 is equal to or greater than 5 MPa, preferably equal to or greater than 6 MPa, and more preferably equal to or greater than 8 MPa. The upper limit of the elastic modulus at 23° C. of the solar cell-encapsulating material configuring the light-receiving surface side-encapsulating layer 11 is equal to or smaller than 30 MPa, preferably equal to or smaller than 28 MPa, more preferably equal to or smaller than 25 MPa, and still more preferably equal to or smaller than 15 MPa. When the elastic modulus at 23° C. of the solar cell-encapsulating material is in the above-described range, even when the effective thickness of the light-receiving surface side-encapsulating layer 11A is equal to or greater than 0.01 mm and smaller than 0.25 mm, it is possible to suppress damage to the solar cell elements or wires during the production of the solar cell module or the repetitive use in environments in which temperatures significantly change, and it is possible to suppress the output reduction of the solar cell module, which is preferable.

Regarding the setting of the elastic modulus at 23° C. of the solar cell-encapsulating material to the above-described range, for example, in a case where the resin (P) is an ethylene.α-olefin copolymer, it is possible to adjust the elastic modulus to the above-described range by adjusting the content proportion of a structural unit derived from an α-olefin or the number of carbon atoms in the α-olefin. In a case where the resin (P) is an ethylene.polar monomer copolymer, it is possible to adjust the elastic modulus to the above-described range by adjusting the content proportion of a structural unit derived from a polar monomer or the type of the polar monomer.

In addition, in order to decrease the elastic modulus at 23° C. of the solar cell-encapsulating material, the solar cell-encapsulating material may further include a lubricant. The content of the lubricant is preferably equal to or greater than 5 parts by mass and equal to or smaller than 30 parts by mass with respect to 100 parts by mass of the total content of the resin (P) and the lubricant.

As the lubricant, well-known lubricants of the related art can be used. Examples of the lubricant include paraffin-based oils, hydrocarbon-based synthetic oils, and the like.

Examples of the paraffin-based oils include paraffin-based process oils (for example, DIANA Process Oil (registered trademark) (manufactured by Idemitsu Kosan Co., Ltd.)), liquid paraffin (for example, MORESCO WHITE (registered trademark) (manufactured by Moresco Corporation)), and the like.

Examples of the hydrocarbon-based synthetic oils include ethylene.α-olefin oligomers (for example, LUCANT (registered trademark) manufactured by Mitsui Chemicals, Inc.)), poly-α-olefins (for example, SpectraSyn (registered trademark) manufactured by Exxon Mobil Corporation)), and the like.

Among these, paraffin-based oils are preferred, and paraffin-based process oils are more preferred.

The average thickness (Y) of the busbar electrode 17 can be measured from a photograph obtained by capturing a cross-section of the busbar electrode 17 using a scanning electron microscope or the like. Specifically, a cross-section of the busbar electrode 17 is captured, ten portions are arbitrarily selected from the obtained photograph, and the thicknesses of the respective portions are respectively measured. In addition, a value obtained by integrating all of the thicknesses and then dividing the sum by 10 can be considered as the average thickness (Y) of the busbar electrode 17.

The depth (Z) of the recess portion 14A of the light-receiving surface-side protective member 14 can be computed using the following method.

First, the basis thickness Z₁=W₂/(D₂×10) of the light-receiving surface-side protective member 14 is computed using the weight W₂ (g/100 cm²) of a 10 cm×10 cm-sized specimen of the light-receiving surface-side protective member 14 and the density D₂ (g/cm³) of the light-receiving surface-side protective member 14.

Next, the apparent thickness Z₂ [mm] of the light-receiving surface-side protective member 14 is measured at the protrusion portion 14B using a film thickness meter such as a dial gauge. Here, the apparent thickness Z₂ of the light-receiving surface-side protective member 14 refers to the thickness of the light-receiving surface-side protective member 14 at the protrusion portion 14B, and, for example, the average value of ten measured thicknesses can be considered as the apparent thickness.

In addition, the depth (Z) of the recess portion 14A can be computed from Z=Z₂−Z₁.

The lower limit of the effective thickness of the rear surface-side encapsulating layer 11B is preferably equal to or greater than 0.01 mm, more preferably equal to or greater than 0.02 mm, still more preferably equal to or greater than 0.05 mm, far still more preferably equal to or greater than 0.07 mm, and particularly preferably equal to or greater than 0.08 mm. In addition, the upper limit of the effective thickness of the rear surface-side encapsulating layer 11B is preferably smaller than 0.25 mm, more preferably equal to or smaller than 0.20 mm, still more preferably smaller than 0.20 mm, far still more preferably equal to or smaller than 0.18 mm, and particularly preferably equal to or smaller than 0.15 mm.

Here, the effective thickness of the rear surface-side encapsulating layer 11B can be measured using the same procedure as for the effective thickness of the light-receiving surface side-encapsulating layer 11A. That is, when the average thickness of the rear surface-side encapsulating layer 11B is represented by A [mm], the average thickness of the busbar electrode 17 on the rear surface side is represented by B [mm], and the depth of a recess portion in a case where the rear surface-side protective member 15 has a plurality of fine recess portions and a plurality of fine protrusion portions on the solar cell electrode 13-side surface is represented by C [mm], the effective thickness of the rear surface-side encapsulating layer 11B is represented by (A-B-C). The respective average thicknesses can be measured using the same method for the measurement of the effective thickness of the light-receiving surface side-encapsulating layer 11A.

As illustrated in FIG. 1, the solar cell module 10 includes a plurality of solar cell elements 13 that is electrically connected together through interconnectors 16. FIG. 1 illustrates an example in which the solar cell elements 13 are connected to one another in series, but the solar cell elements 13 may be connected to one another in parallel. The light-receiving surface-side protective member 14 and the rear surface-side protective member 15 sandwich the solar cell elements 13, and the space between the protective members and the plurality of solar cell elements 13 is filled with the encapsulating layer 11. The encapsulating layer 11 is configured by the light-receiving surface side-encapsulating layer 11A and the rear surface-side encapsulating layer 11B, the light-receiving surface side-encapsulating layer 11A is in contact with electrodes formed on the light-receiving surfaces of the solar cell elements 13, and the rear surface-side encapsulating layer 11B is in contact with electrodes formed on the solar cell elements 13 rear surface. The electrodes are power collection members that are respectively formed on the light-receiving surfaces and the rear surfaces of the solar cell elements 13, and finger electrodes described below, the busbar electrodes, rear surface electrode layers, and the like can be considered as the electrodes.

The thickness of the rear surface-side encapsulating layer 11B may be identical to or different from the thickness of the light-receiving surface side-encapsulating layer 11A, but is preferably equal to or smaller than 0.60 mm from the viewpoint of the size reduction of the module and is preferably in a range of 0.40 to 0.60 mm and more preferably in a range of 0.43 to 0.55 mm from the viewpoint of handling.

The encapsulating layer 11 is formed of a solar cell-encapsulating material S made of a resin composition. The solar cell-encapsulating material S preferably has a sheet-like shape and may or may not be cross-linked as necessary. Hereinafter, the solar cell-encapsulating material S that is used to form the encapsulating layer 11 will be described.

The solar cell-encapsulating material S may be configured by a pair of a first solar cell-encapsulating material S1 that forms the light-receiving surface side-encapsulating layer 11A and a second solar cell-encapsulating material S2 that forms the rear surface-side encapsulating layer 11B. Hereinafter, the solar cell-encapsulating material S will also be used as a collective term for the first solar cell-encapsulating material S1 and the second solar cell-encapsulating material S2.

The solar cell-encapsulating material S is preferably configured by a resin composition including at least one type of resin (P) selected from a polyolefin-based resin and an ethylene.polar monomer copolymer. In addition, the first solar cell-encapsulating material S1 configuring the light-receiving surface side-encapsulating layer 11A more preferably includes a polyolefin-based resin as the resin (P), and both the first solar cell-encapsulating material S1 and the second solar cell-encapsulating material S2 still more preferably include a polyolefin-based resin.

When the total content of the light-receiving surface side-encapsulating layer 11A (the first solar cell-encapsulating material S1) is set to 100% by mass, the content of the resin (P) in the light-receiving surface side-encapsulating layer 11A (the first solar cell-encapsulating material S1) in the present embodiment is preferably equal to or greater than 50% by mass, more preferably equal to or greater than 70% by mass, still more preferably equal to or greater than 80% by mass, and particularly preferably equal to or greater than 90% by mass. In such a case, it is possible to obtain the light-receiving surface side-encapsulating layer 11A being more favorable in terms of the balance of a variety of characteristics such as transparency, adhesiveness, heat resistance, flexibility, cross-linking characteristics, and the like.

In addition, when the total content of the rear surface-side encapsulating layer 11B (the second solar cell-encapsulating material S2) is set to 100% by mass, the content of the resin (P) in the rear surface-side encapsulating layer 11B (the first solar cell-encapsulating material S2) in the present embodiment is preferably equal to or greater than 50% by mass, more preferably equal to or greater than 70% by mass, still more preferably equal to or greater than 80% by mass, and particularly preferably equal to or greater than 90% by mass. In such a case, it is possible to obtain the rear surface-side encapsulating layer 11B being more favorable in terms of the balance of a variety of characteristics such as adhesiveness, heat resistance, flexibility, cross-linking characteristics, and the like.

Examples of the polyolefin-based resin include one or more types selected from ethylene.α-olefin copolymers, low-density ethylene-based resins, medium-density ethylene-based resins, ultralow-density ethylene-based resins, propylene (co)polymers, 1-butene (co)polymers, 4-methylpentene-1 (co)polymers, ethylene.cyclic olefin copolymers, ethylene.α-olefin.cyclic olefin copolymers, ethylene.α-olefin.nonconjugated polyene copolymers, ethylene.α-olefin.conjugated polyene copolymers, ethylene.aromatic vinyl copolymers, and ethylene.α-olefin.aromatic vinyl copolymers.

In addition, the first solar cell-encapsulating material S1 preferably includes an ethylene.α-olefin copolymer as the polyolefin-based resin. In such a case, it is possible to form the light-receiving surface side-encapsulating layer 11A including an ethylene.α-olefin copolymer.

The second solar cell-encapsulating material S2 may be formed of the same composition as the first solar cell-encapsulating material S1, may be formed of a different composition, or may include an ethylene.α-olefin copolymer as the resin (P). Both the first solar cell-encapsulating material S1 and the second solar cell-encapsulating material S2 may include an ethylene.α-olefin copolymer. In such a case, the entire encapsulating layer 11 can be formed by cross-linking a resin composition including an ethylene.α-olefin copolymer.

The ethylene.α-olefin copolymer included in the solar cell-encapsulating material S is more preferably an ethylene.α-olefin copolymer made up of ethylene and an α-olefin having 3 to 20 carbon atoms. As the α-olefin, generally, one type of α-olefin having 3 to 20 carbon atoms can be used singly or two or more types of α-olefins can be used in combination. Among these, an α-olefin having 10 or less carbon atoms is preferred, and an α-olefin having 3 to 8 carbon atoms is particularly preferred. Specific examples of the α-olefin include propylene, 1-butene, 1-pentene, 1-hexene, 3-methyl-1-butene, 3,3-dimethyl-1-butene, 4-methyl-1-pentene, 1-octene, 1-decene, 1-dodecene, and the like. Among these, propylene, 1-butene, 1-pentene, 1-hexene, 4-methyl-1-pentene, and 1-octene are preferred from the viewpoint of the ease of procurement. Meanwhile, the ethylene.α-olefin copolymer may be a random copolymer or a block copolymer, but is preferably a random copolymer from the viewpoint of flexibility.

In addition, as the ethylene.α-olefin copolymer, an ethylene.α-olefin copolymer satisfying at least one of a1) to a4) described below is preferably used.

a1) The content proportion of a structural unit derived from ethylene is in a range of 80 to 90 mol %, and the content proportion of a structural unit derived from an α-olefin having 3 to 20 carbon atoms is in a range of 10 to 20 mol %,

a2) MFR, which is on the basis of ASTM D1238 and is measured under conditions of 190° C. and a load of 2.16 kg, is in a range of 0.1 to 50 g/10 minutes,

a3) the density, which is measured on the basis of ASTM D1505, is in a range of 0.865 to 0.884 g/cm³, and

a4) the Shore A hardness, which is measured on the basis of ASTM D2240, is in a range of 60 to 85.

The ethylene.α-olefin copolymer that is used in the solar cell-encapsulating material S more preferably satisfies any two of a1) to a4), still more preferably satisfies any three of a1) to a4), and particularly preferably satisfies three of a1), a3), and a4). The ethylene.α-olefin copolymer particularly preferably satisfies all of a1) to a4). Hereinafter, a1) to a4) will be described.

a1)

The proportion of the structural unit which is included in the ethylene.α-olefin copolymer and is derived from an α-olefin having 3 to 20 carbon atoms (hereinafter, also referred to as “α-olefin unit”) is preferably in a range of 10 to 20 mol %, more preferably in a range of 12 to 20 mol %, still more preferably in a range of 12 to 18 mol %, and particularly preferably in a range of 13 to 18 mol %. When the content proportion of the α-olefin unit is set to equal to or greater than 10 mol %, there is a tendency that highly transparent encapsulating layers 11 are obtained. In addition, since the encapsulating layer is highly flexible, it is possible to further suppress the generation of cracks in the solar cell elements 13, chips in thin-film electrodes, and the like. Meanwhile, when the content proportion of the α-olefin unit is equal to or smaller than 20 mol %, sheets which can be easily turned into sheets and have favorable blocking resistance can be obtained, and it is possible to improve heat resistance when the encapsulating layer is cross-linked.

a2)

The melt flow rate (MFR) of the ethylene.α-olefin copolymer, which is on the basis of ASTM D1238 and measured under conditions of 190° C. and a load of 2.16 kg, is generally in a range of 0.1 to 50 g/10 minutes, preferably in a range of 2 to 50 g/10 minutes, more preferably in a range of 10 to 50 g/10 minutes, still more preferably in a range of 10 to 40 g/10 minutes, particularly preferably in a range of 12 to 27 g/10 minutes, and most preferably in a range of 15 to 25 g/10 minutes. The MFR of the ethylene.α-olefin copolymer can be adjusted by adjusting polymerization temperatures and polymerization pressures during polymerization reactions described below, the molar ratio between monomer concentrations and hydrogen concentrations in ethylene and the α-olefin in polymerization systems, and the like.

(Calender Molding)

When the MFR is equal to or greater than 0.1 g/10 minutes and smaller than 10 g/10 minutes, it is possible to manufacture sheets through calender molding. When the MFR is equal to or greater than 0.1 g/10 minutes and smaller than 10 g/10 minutes, the fluidity of the resin composition including the ethylene.α-olefin copolymer is low, and thus it is possible to prevent laminating devices from being contaminated by molten resins extracted when sheets are laminated together with the cell elements, which is preferable.

(Extrusion Molding)

When the MFR is equal to or greater than 2 g/10 minutes and preferably equal to or greater than 10 g/10 minutes, the fluidity of the resin composition including the ethylene.α-olefin copolymer improves, and it is possible to improve the productivity during sheet extrusion molding.

When the MFR is set to equal to or smaller than 50 g/10 minutes, the molecular weight increases, and thus it is possible to suppress adhesion to roll surfaces of chilled rolls or the like, and thus peeling is not required, and it is possible to mold sheets having a uniform thickness. Since the resin composition becomes “elastic”, it is possible to easily mold sheets having a thickness of equal to or greater than 0.1 mm. In addition, the cross-linking characteristics during the lamination molding of the solar cell module improve, and thus the resin composition is sufficiently cross-linked, and it is possible to suppress the degradation of heat resistance.

When the MFR is equal to or smaller than 27 g/10 minutes, it is possible to suppress drawdown during sheet molding and mold sheets having a wide width, cross-linking characteristics and heat resistance further improve, and it is possible to obtain most favorable solar cell-encapsulating material sheets.

Meanwhile, in a case where the cross-linking treatment of the resin composition is not performed in the laminate process of the solar cell module described below, the decomposition of organic peroxides in a melt extrusion step only has a small influence, and thus it is also possible to obtain sheets through extrusion molding using resin compositions in which the MFR is equal to or greater than 0.1 g/10 minutes and smaller than 10 g/10 minutes and preferably equal to or greater than 0.5 g/10 minutes and smaller than 8.5 g/10 minutes. In a case where the content of organic peroxides in the resin composition is equal to or smaller than 0.15 parts by weight, it is also possible to manufacture sheets using a resin composition in which the MFR is equal to or greater than 0.1 g/10 minutes and smaller than 10 g/10 minutes through extrusion molding at a molding temperature in a range of 170° C. to 250° C. while performing a silane modification treatment or a fine cross-linking treatment. When the MFR is in the above-described range, it is possible to prevent laminating devices from being contaminated by molten resins extracted when sheets are laminated together with the solar cell elements, which is preferable.

a3)

The density of the ethylene.α-olefin copolymer, which is measured on the basis of ASTM D1505, is 0.865 to 0.884 g/cm³, preferably 0.866 to 0.883 g/cm³, more preferably 0.866 to 0.880 g/cm³, and still more preferably 0.867 to 0.880 g/cm³. The density of the ethylene.α-olefin copolymer can be adjusted using the balance between the content proportion of an ethylene unit and the content proportion of an α-olefin unit. That is, when the content proportion of the ethylene unit is increased, crystallinity increases, and ethylene.α-olefin copolymers having a high density can be obtained. On the other hand, when the content proportion of the ethylene unit is decreased, crystallinity decreases, and ethylene.α-olefin copolymers having a low density can be obtained. When the density of the ethylene.α-olefin copolymer is equal to or smaller than 0.884 g/cm³, it is possible to improve transparency and flexibility. On the other hand, when the density of the ethylene.α-olefin copolymer is equal to or greater than 0.865 g/cm³, sheets which can be easily turned into sheets and have favorable blocking resistance can be obtained, and it is possible to improve heat resistance.

a4)

The Shore A hardness of the ethylene.α-olefin copolymer, which is measured on the basis of ASTM D2240, is in a range of 60 to 85, preferably in a range of 62 to 83, more preferably in a range of 62 to 80, and still more preferably in a range of 65 to 80. The Shore A hardness of the ethylene.α-olefin copolymer can be adjusted by controlling the content proportion or density of the ethylene unit in the ethylene.α-olefin copolymer to a numerical range described below. That is, the Shore A hardness becomes great in the ethylene.α-olefin copolymer having a high content proportion of the ethylene unit and a high density. On the other hand, the Shore A hardness becomes low in the ethylene.α-olefin copolymer having a low content proportion of the ethylene unit and a low density. When the Shore A hardness is equal to or greater than 60, sheets which can be easily turned into sheets and have favorable blocking resistance can be obtained, and it is possible to improve heat resistance. On the other hand, when the Shore A hardness is equal to or smaller than 85, it is possible to improve transparency and flexibility, and it is possible to easily perform sheet molding.

The ethylene.α-olefin copolymer can be manufactured using a variety of metallocene compounds described below as a catalyst. As the metallocene compounds, for example, it is possible to use the metallocene compounds described in Japanese Laid-open Patent Publication No. 2006-077261, Japanese Laid-open Patent Publication No. 2008-231265, Japanese Laid-open Patent Publication No. 2005-314680 and the like. Here, metallocene compounds having a different structure from those of the metallocene compounds described in the above-described patent documents may also be used, and two or more types of metallocene compounds may also be used in combination.

The polymerization of the ethylene.α-olefin copolymer can be performed using any one of well-known gas-phase polymerization methods of the related art and liquid-phase polymerization methods such as a slurry polymerization method and a solution polymerization method. The polymerization is preferably performed using a liquid-phase polymerization method such as a solution polymerization method.

Examples of the ethylene.polar monomer copolymer include one or more types selected from ethylene.unsaturated carboxylic acid ester copolymers such as ethylene.ethyl (meth)acrylate copolymers, ethylene.methyl (meth)acrylate copolymers, ethylene.propyl (meth)acrylate copolymers, ethylene.butyl (meth)acrylate copolymers, ethylene.hexyl (meth)acrylate copolymers, ethylene.(meth)acrylic acid-2-hydroxyethyl copolymers, ethylene.(meth)acrylic acid-2-hydroxypropyl copolymers, ethylene.glycidyl (meth)acrylate copolymers, ethylene.dimethyl maleate copolymers, ethylene.dimethyl fumarate copolymers, and ethylene.diethyl fumarate copolymers; ethylene.unsaturated carboxylic acid copolymers such as ethylene.(meth)acrylic acid copolymers (including ionomers), ethylene.maleic acid copolymers, ethylene.fumaric acid copolymers, and ethylene.crotonic acid copolymers and salts thereof; ethylene.vinyl ester copolymers such as ethylene.vinyl acetate copolymers, ethylene.vinyl propionate copolymers, ethylene.vinyl stearate copolymers; ethylene.styrene copolymers; and the like.

Among these, from the viewpoint of the balance between the ease of procurement and performance, the resin composition preferably includes, as the ethylene.polar monomer copolymer, one or more types selected from ethylene.unsaturated carboxylic acid copolymers and salts thereof, ethylene.vinyl ester copolymers, and ethylene.unsaturated carboxylic acid ester copolymers, preferably includes one or more types selected from ethylene.vinyl acetate copolymers, ethylene.ethyl (meth)acrylate copolymers, ethylene.methyl (meth)acrylate copolymers, ethylene.propyl (meth)acrylate copolymers, ethylene.butyl (meth)acrylate copolymers, and ethylene.(meth)acrylic acid copolymers (including ionomers), and ethylene.vinyl acetate copolymers are particularly preferred.

The content of a polar monomer unit in the ethylene.polar monomer copolymer is preferably equal to or greater than 8% by mass and equal to or smaller than 40% by mass, more preferably equal to or greater than 10% by mass and equal to or smaller than 35% by mass, and still more preferably equal to or greater than 13% by mass and equal to or smaller than 35% by mass. When the content of the polar monomer is in this range, the balance between cross-linking properties, flexibility, weather resistance, and transparent is more favorable.

Among these, ethylene.vinyl acetate copolymers are preferred, and ethylene.vinyl acetate copolymers in which the content proportion of a structural unit derived from vinyl acetate is preferably equal to or greater than 26% by mass and equal to or smaller than 40% by mass and more preferably equal to or greater than 29% by mass and equal to or smaller than 35% by mass can be most preferably used.

The solar cell-encapsulating material S preferably contains, in addition to the resin (P), one or more types selected from a silane coupling agent; a cross-linking agent such as a photocross-linking initiator or an organic peroxide; and the like.

The content of the silane coupling agent is, for example, preferably set in a range of 0.1 to 5 parts by weight and more preferably set in a range of 0.1 to 4 parts by weight with respect to 100 parts by weight of the resin (P).

The content of the cross-linking agent is, for example, preferably set in a range of 0.05 to 5 parts by weight and more preferably set in a range of 0.1 to 3 parts by weight with respect to 100 parts by weight of the resin (P).

As the silane coupling agent, well-known silane coupling agents of the related art can be used, and there is no particular limitation. Specifically, vinyltriethoxysilane, vinyltrimethoxysilane, vinyltris(β-methoxyethoxysilane), γ-glycidoxypropyltrimethoxysilane, γ-aminopropyltriethoxysilane, γ-methacryloxypropyltrimethoxysilane, or the like can be used. Preferred examples thereof include one or more types selected from γ-glycidoxypropylmethoxysilane, γ-aminopropyltriethoxysilane, γ-methacryloxypropyltrimethoxysilane, vinyltriethoxysilane, and the like.

The organic peroxide is used as a radical initiator during the graft modification of the silane coupling agent and the resin (P) and, furthermore, as a radical initiator during cross-linking reactions when the resin (P) is laminate-molded to the solar cell module. When the silane coupling agent is graft-modified into the resin (P), the solar cell module 10 having a favorable adhesiveness between the light-receiving surface-side protective member 14, the rear surface-side protective member 15, the solar cell elements 13, and the electrodes can be obtained. Furthermore, when the resin (P) is cross-linked, the solar cell module 10 having excellent heat resistance and adhesiveness can be obtained.

As the organic peroxide, well-known organic peroxides can be used. Specific examples thereof include dilauroyl peroxide, 1,1,3,3-tetramethylbutyl peroxy-2-ethylhexanoate, dibenzoyl peroxide, t-amyl peroxy-2-ethylhexanoate, t-butyl peroxy-2-ethylhexanoate, t-butyl peroxy isobutyrate, t-butyl peroxy maleate, 1,1-di(t-amyl peroxy)-3,3,5-trimethylcyclohexane, 1,1-di(t-amyl peroxy)cyclohexane, t-amyl peroxy isononanoate, t-amyl peroxy normal octoate, 1,1-di(t-butyl peroxy)-3,3,5-trimethylcyclohexane, 1,1-di(t-butyl peroxy) cyclohexane, t-butyl peroxy isopropyl carbonate, t-butyl peroxy-2-ethylhexyl carbonate, 2,5-dimethyl-2,5-di(benzoyl peroxy) hexane, t-amyl-peroxy benzoate, t-butyl peroxy acetate, t-butyl peroxy isononanoate, 2,2-di(t-butyl peroxy)butane, and t-butyl peroxy benzoate. Preferred examples thereof include dilauroyl peroxide, t-butyl peroxy isopropyl carbonate, t-butyl peroxy acetate, t-butyl peroxy isononanoate, t-butyl peroxy-2-ethylhexyl carbonate, t-butyl peroxy benzoate, and the like. One type of organic peroxide may be used singly or two or more types of organic peroxides may be used in combination.

In addition, as the photocross-linking initiator, for example, one or more types of photocross-linking initiators selected from the group consisting of benzophenone, benzophenone derivatives, thioxanthone, thioxanthone derivatives, benzoin, benzoin derivatives, α-hydroxyalkylphenones, α-aminoalkylphenols, acylphosphinoxides, alkylphenylglyoxylates, diethoxyacetophenone, oxime esters, titanocene compounds, anthraquinone derivative, and the like can be used. Among these, benzophenone, benzophenone derivatives, benzoin, benzoin derivatives, α-hydroxyalkylphenones, oxime esters, and anthraquinone derivative are preferred from the viewpoint of more favorable cross-linking properties, benzophenone, benzophenone derivatives, and anthraquinone derivative are more preferred, and benzophenone and benzophenone derivatives are most preferred since the transparency is also favorable.

Among the benzophenone derivatives, 2-hydroxybenzophenone is used as an ultraviolet absorbing agent as described below and has an action of converting light to heat energy. The photocross-linking initiator of the present embodiment is desirably a benzophenone derivative not having a hydroxyl group in the second place.

Preferred examples of benzophenone and the benzophenone derivatives include benzophenone, 4-phenylbenzophenone, 4-phenoxybenzophenone, 4,4-bis(diethylamino) benzophenone, methyl o-benzoylbenzoate, 4-methylbenzophenone, 2,4,6-trimethylbenzophenone, and the like.

Preferred examples of the anthraquinone derivatives include 2-methyl anthraquinone, 2-ethyl anthraquinone, 2-t-butyl anthraquinone, 1-chloroanthraquinone, and the like.

One type of photocross-linking initiator can be used singly or two or more types of photocross-linking initiators can also be used in combination.

To the solar cell-encapsulating material S, it is preferable to add at least one type of additive selected from the group consisting of an ultraviolet absorbing agent, a light stabilizer, and a heat-resistance stabilizer. The blending amount of these additives is preferably in a range of 0.005 to 5 parts by weight with respect to 100 parts by weight of the resin (P). Furthermore, the solar cell-encapsulating material preferably contains at least two types of additives selected from the above-described three types of additives and particularly preferably contains all of the three types of additives. When the blending amount of the additives is within the above-described range, an effect of improving the resistance to high temperature and high humidity, the resistance to heat cycles, weather resistance stability, and heat resistance stability is sufficiently ensured, and it is possible to prevent the degradation of the transparency of the solar cell-encapsulating material S or the adhesiveness to the light-receiving surface-side protective member 14, the rear surface-side protective member 15, the solar cell elements 13, the electrodes, and aluminum, which is preferable.

As the ultraviolet absorbing agent, specifically, a benzophenone-based ultraviolet absorbing agent such as 2-hydroxy-4-normal-octyloxy benzophenone, 2-hydroxy-4-methoxy benzophenone, 2,2-dihydroxy-4-methoxy benzophenone, 2-hydroxy-4-methoxy-4-carboxy benzophenone, and 2-hydroxy-4-N-octoxy benzophenone; a benzotriazole-based ultraviolet absorbing agent such as 2-(2-hydroxy-3,5-di-t-butyl phenyl)benzotriazole and 2-(2-hydroxy-5-methyl phenyl)benzotriazole; or a salicylic acid ester-based ultraviolet absorbing agent such as phenyl salicylate and p-octyl phenyl salicylate is used. One type of ultraviolet absorbing agent can be used singly or two or more types of ultraviolet absorbing agents can be used in combination.

As the light stabilizer, hindered amine-based compounds, hindered piperidine-based compounds, and the like such as bis(2,2,6,6-tetramethyl-4-piperidyl)sebacate, and poly[{6-(1,1,3,3-tetramethyl butyl)amino-1,3,5-triazine-2,4-diyl} {(2,2,6,6-tetramethyl-4-piperidyl)imino}hexamethylene {(2,2,6,6-tetramethyl-4-piperidyl)imino}] are preferably used. One type of light stabilizer can be used singly or two or more types of light stabilizers can be used in combination.

Specific examples of the heat-resistance stabilizer include a phosphite-based heat-resistance stabilizer such as tris(2,4-di-tert-butylphenyl)phosphite, bis[2,4-bis(1,1-dimethylethyl)-6-methylphenyl]ethyl ester phosphite, tetrakis(2,4-di-tert-butylphenyl) [1,1-biphenyl]-4,4′-diyl bis phosphonites, and bis(2,4-di-tert-butylphenyl)pentaerythritol diphosphite; a lactone-based heat-resistance stabilizer such as a reaction product between 3-hydroxy-5,7-di-tert-butyl-furan-2-one and o-xylene; a hindered phenol-based heat-resistance stabilizer such as 3,3′,3″,5,5′,5″-hexa-tert-butyl-a,a′,a″-(methylene-2,4,6-triyl)tri-p-cresol, 1,3,5-trimethyl-2,4,6-tris(3,5-di-tert-butyl-4-hydroxyphenyl)benzylbenzene, pentaerythritol tetrakis[3-(3,5-di-tert-butyl-4-hydroxyphenyl)propionate], octadecyl-3-(3,5-di-tert-butyl-4-hydroxyphenyl)propionate, and thiodiethylene bis[3-(3,5-di-tert-butyl-4-hydroxyphenyl)propionate]; a sulfur-based heat-resistance stabilizer; and an amine-based heat-resistance stabilizer. It is also possible to singly use one type of heat-resistance stabilizer or use two or more types of heat-resistance stabilizers in combination. Among these materials, the phosphite-based heat-resistance stabilizer and the hindered phenol-based heat-resistance stabilizer are preferable.

To the solar cell-encapsulating material S, it is possible to appropriately add a variety of components other than the components described above in detail within the scope of the purpose of the present invention. For example, the solar cell-encapsulating material is capable of appropriately containing one or more types of additives selected from a variety of resins other than the resin (P) and/or a variety of rubbers, a plasticizer, a lubricant, a filler, a pigment, a dye, an antistatic agent, an antimicrobial agent, an antifungal agent, a flame retardant, a cross-linking assistant, a dispersant, and the like.

In a case where the cross-linking assistant is added to the solar cell-encapsulating material S, when the blending amount of the cross-linking assistant is in a range of 0.05 to 5 parts by weight with respect to 100 parts by weight of the resin (P), the solar cell-encapsulating material is capable of having an appropriate cross-linking structure, and is capable of improving heat resistance, mechanical properties, and adhesiveness, which is preferable.

As the cross-linking assistant, well-known cross-linking assistants of the related art which are generally used with respect to the resin (P) can be used. The cross-linking assistant is a compound having equal to or greater than two double bonds in the molecule. Specific examples thereof include monoacrylate such as t-butyl acrylate, lauryl acrylate, cetyl acrylate, stearyl acrylate, 2-methoxyethyl acrylate, ethyl carbitol acrylate, and methoxy tripropylene glycol acrylate; monomethacrylate such as t-butyl methacrylate, lauryl methacrylate, cetyl methacrylate, stearyl methacrylate, methoxyethylene glycol methacrylate, methoxypolyethylene glycol methacrylate; diacrylate such as 1,4-butanediol diacrylate, 1,6-hexanediol diacrylate, 1,9-nonanediol diacrylate, neopentyl glycol diacrylate, diethylene glycol diacrylate, tetraethylene glycol diacrylate, polyethylene glycol diacrylate, tripropylene glycol diacrylate, and polypropylene glycol diacrylate; dimethacrylate such as 1,3-butanediol dimethacrylate, 1,6-hexanediol dimethacrylate, 1,9-nonanediol dimethacrylate, neopentyl glycol dimethacrylate, ethylene glycol dimethacrylate, diethylene glycol dimethacrylate, triethylene glycol dimethacrylate, and polyethylene glycol dimethacrylate; triacrylate such as trimethylol propane triacrylate, tetramethylol methane triacrylate, and pentaerythritol triacrylate; trimethacrylate such as trimethylol propane trimethacrylate, and trimethylol ethane trimethacrylate; tetraacrylate such as pentaerythritol tetraacrylate and tetramethylol methane tetraacrylate; divinyl aromatic compounds such as divinylbenzene and di-i-propenyl benzene; cyanurate such as triallyl cyanurate and triallyl isocyanurate; diallyl compounds such as diallyl phthalate; triallyl compounds; oxime such as p-quinone dioxime and p-p′-dibenzoyl quinone dioxime; and maleimide such as phenyl maleimide. Among these cross-linking assistants, diacrylate, dimethacrylate, divinyl aromatic compound, triacrylate such as trimethylol propane triacrylate, tetramethylol methane triacrylate, and pentaerythritol triacrylate; trimethacrylate such as trimethylolpropane trimethacrylate and trimethylolethane trimethacrylate; tetraacrylate such as pentaerythritol tetraacrylate and tetramethylolmethane tetraacrylate; cyanurate such as triallyl cyanurate and triallyl isocyanurate; diallyl compounds such as diallyl phthalate; triallyl compounds; oxime such as p-quinone dioxime and p-p′-dibenzoyl quinone dioxime; and maleimide such as phenyl maleimide are preferable. Furthermore, among these materials, triallyl isocyanurate is particularly preferable, which is most favorable in terms of the balance between the generation of air bubbles in the encapsulating layer 11 or the cross-linking characteristics. One type of cross-linking assistant can be used singly or two or more types of cross-linking assistants can be used in combination.

The method for molding the solar cell-encapsulating material S is not particularly limited, and it is possible to employ a variety of well-known molding methods (cast molding, extrusion sheet molding, inflation molding, injection molding, compression molding, calender molding, and the like).

In addition, in a case where the solar cell-encapsulating material S is turned into a sheet, embossing may be performed on the sheet surface. When the sheet surface of the solar cell-encapsulating material S is decorated by means of embossing, it is possible to prevent blocking between sheets or between the sheet-like solar cell-encapsulating material S and other members. Furthermore, embosses decrease the storage elastic modulus of the solar cell-encapsulating material S and thus serve as cushions for the solar cell elements 13 and the like when the solar cell-encapsulating material S and the solar cell elements 13 are laminated together, and thus it is possible to further prevent damage to the solar cell elements 13.

The light-receiving surface-side protective member 14 is not particularly limited, but is located on the outermost surface layer of the solar cell module, and thus the light-receiving surface-side protective member preferably has performances for ensuring long-term reliability for the outdoor exposure of the solar cell module, mainly, weather resistance, water repellency, contamination resistance, and mechanical strength. In addition, the light-receiving surface-side protective member is preferably a sheet having a small optical loss and high transparency in order for the effective use of sunlight. Examples of the light-receiving surface-side protective member 14 include glass plates, resin films, and the like.

Examples of resins configuring the resin films include polyester resins, fluororesins, acrylic resins, cyclic olefin (co)polymers, ethylene-vinyl acetate copolymers, and the like.

The light-receiving surface-side protective member 14 has the plurality of fine recess portions 14A and the plurality of fine protrusion portions 14B on at least the solar cell electrode 13-side surface. Therefore, it is possible to improve the adhesiveness between the light-receiving surface-side protective member 14 and the light-receiving surface side-encapsulating layer 11A. In addition, it is possible to impart an anti-glare effect to the solar cell module by scattering light and thus decreasing the reflectivity.

The plurality of fine recess portions 14A and the plurality of fine protrusion portions 14B can be formed using well-known methods of the related art. For example, the recess portions and the protrusion portions can be formed using a method in which recesses and protrusions are directly imparted to the surface of the light-receiving surface-side protective member 14 using a physical method or a chemical method, a method in which an irregular reflection layer including an uneven surface is formed on the surface of the light-receiving surface-side protective member 14, or the like.

Examples of the method in which recesses and protrusions are directly imparted to the surface of the light-receiving surface-side protective member 14 using a physical method or a chemical method include embossing, pressing, laser patterning, and the like.

Examples of the method in which an irregular reflection layer including an uneven surface is formed on the surface of the light-receiving surface-side protective member 14 include a method in which a composition including an organic binder and inorganic particles is applied onto the surface of the light-receiving surface-side protective member 14, a method in which a composition including an organic binder and inorganic particles that is applied onto the surface of a base material is transferred to the surface of the light-receiving surface-side protective member 14, and the like.

Among these, the method in which the plurality of fine recess portions 14A and the plurality of fine protrusion portions 14B are formed by embossing the surface of the light-receiving surface-side protective member 14 is preferred since it is possible to easily form the plurality of fine recess portions 14A and the plurality of fine protrusion portions 14B having desired shapes on the surface of the light-receiving surface-side protective member 14.

The basis thickness Z₁ of the light-receiving surface-side protective member 14 is preferably equal to or greater than 1 mm and equal to or smaller than 5 mm and more preferably equal to or greater than 2 mm and equal to or smaller than 4 mm.

The depth (Z) of the recess portion 14A of the light-receiving surface-side protective member 14 is preferably equal to or greater than 0.02 mm and equal to or smaller than 0.5 mm and more preferably equal to or greater than 0.04 mm and equal to or smaller than 0.1 mm.

The rear surface-side protective member 15 does not need to be transparent and is not particularly limited, but is located on the outermost surface layer of the solar cell module 10, and thus, similar to the light-receiving surface-side protective member 14, a variety of characteristics such as weather resistance and mechanical strength are required. Therefore, the rear surface-side protective member 15 may be configured by the same material as the light-receiving surface-side protective member 14. That is, a variety of the above-described materials that are used for the light-receiving surface-side protective member 14 can also be used for the rear surface-side protective member 15. Particularly, it is possible to preferably use polyester resins and glass. In addition, the rear surface-side protective member 15 does not have a precondition of transmitting sunlight, and thus transparency required for the light-receiving surface-side protective member 14 is not always required. Therefore, a reinforcement plate may be attached thereto in order to increase the mechanical strength of the solar cell module 10 or prevent strain and warpage caused by temperature changes. As the reinforcement plate, for example, it is possible to preferably use steel plates, plastic plates, glass fiber reinforced plastic (FRP) plates, and the like.

The solar cell element 13 that is used in the solar cell module 10 is not particularly limited as long as the solar cell element is capable of generating power using the photovoltaic effect of semiconductors. FIG. 1 illustrates an example in which crystal-type solar cell elements are used as the solar cell elements 13, but it is also possible to use compound semiconductor (III-III group, II-VI group, and the like) solar cell elements, wet-type solar cell elements, organic semiconductor solar cell elements, and the like. The crystal-type solar cell elements are solar cell elements formed of single crystal-type, polycrystal-type, or amorphous-type silicon or the like, and, among these, solar cell elements formed of polycrystal-type silicon are more preferred from the viewpoint of the balance between power generation performance and costs and the like.

The average thickness (excluding the thickness of the power collection electrode) of the solar cell elements 13 is generally equal to or greater than 0.3 mm and equal to or smaller than 0.5 mm. However, from the viewpoint of cost reduction and thickness reduction, the thickness of the solar cell element 13 is preferably equal to or greater than 0.01 mm and equal to or smaller than 0.5 mm and more preferably equal to or greater than 0.01 mm and equal to or smaller than 0.3 mm. In the solar cell module 10 of the present embodiment, even when the thickness of the solar cell element 13 is thin as described above, it is possible to prevent damage to the solar cell elements 13.

Meanwhile, the average thickness of the solar cell element 13 can be measured from a photograph obtained by capturing a cross-section of the solar cell element 13 using a scanning electron microscope or the like. Specifically, a cross-section of the solar cell element 13 is captured, ten portions are arbitrarily selected from the obtained photograph, and the thicknesses of the respective portions are respectively measured. In addition, a value obtained by integrating all of the thicknesses and then dividing the sum by 10 can be considered as the average thickness of the solar cell element 13.

In the solar cell element, generally, a power collection electrode for removing generated electricity is disposed. Examples of the power collection electrode include busbar electrodes, finger electrodes, and the like. Generally, power collection electrodes are disposed on both surfaces (the front surface and the rear surface) of the solar cell element; however, in a case where a power collection electrode is disposed on the light-receiving surface, the power collection electrode needs to be disposed so as to prevent a decrease in the power generation efficiency as much as possible.

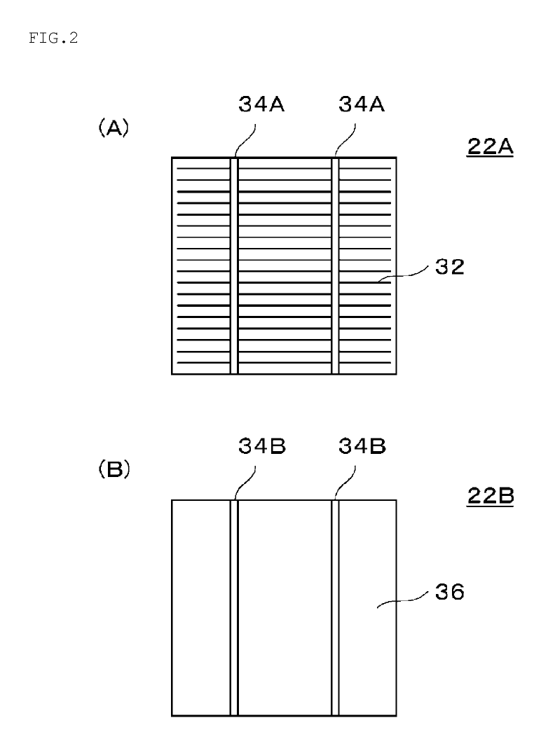

FIG. 2 is a schematic plan view illustrating one configuration example of the light-receiving surface and the rear surface of the solar cell element 13. FIG. 2 illustrates an example of the configuration of a light-receiving surface 22A and a rear surface 22B of the solar cell element 13. As illustrated in FIG. 2A, on the light-receiving surface 22A of the solar cell element 13, a number of finger electrodes 32 that are linearly formed and busbar electrodes 34A which collect charges from the finger electrodes 32 and are connected to the interconnectors 16 (FIG. 1) are formed. In addition, as illustrated in FIG. 2B, on the rear surface 22B of the solar cell element 13, a conductive layer (rear surface electrode) 36 is formed so as to cover the entire surface, and busbar electrodes 34B which collect charges from the conductive layer 36 and are connected to the interconnectors 16 (FIG. 1) are formed.

The linear width of the finger electrode 32 is, for example, approximately 0.2 mm; the linear width of the busbar electrode 34A is, for example, approximately in a range of 2 to 3 mm; and the linear width of the busbar electrode 34B is, for example, approximately in a range of 5 to 7 mm.

The average thickness (Y) of the busbar electrode is not particularly limited, but is preferably equal to or greater than 0.02 mm and equal to or smaller than 0.6 mm and more preferably equal to or greater than 0.04 mm and equal to or smaller than 0.5 mm. When the average thickness (Y) of the busbar electrode is equal to or greater than the above-described lower limit value, it is possible to more efficiently collect generated electricity. When the average thickness (Y) of the busbar electrode is equal to or smaller than the above-described upper limit value, it is possible to obtain solar cell modules having a thinner thickness.

The average thickness of the finger electrode is not particularly limited, but is preferably equal to or greater than 0.01 mm and equal to or smaller than 0.1 mm and more preferably equal to or greater than 0.02 mm and equal to or smaller than 0.07 mm. When the average thickness of the finger electrode is equal to or greater than the above-described lower limit value, it is possible to more efficiently collect generated electricity. When the average thickness of the finger electrode is equal to or smaller than the above-described upper limit value, it is possible to obtain solar cell modules having a thinner thickness.

In the present embodiment, in a case in which the average thickness (Y) of the busbar electrode varies on the light-receiving surface 22A and the rear surface 22B of the solar cell element 13, the effective thickness of the light-receiving surface side-encapsulating layer 11A is determined using the average thickness (Y) of the busbar electrode on the light-receiving surface 22A side. In such a case, it is possible to more reliably suppress damage to the solar cell element 13.

As the interconnector 16, an interconnector configured by, for example, a copper foil or the like is used. The average thickness of the interconnector 16 is not particularly limited and, for example, equal to or greater than 0.15 mm and equal to or smaller than 1.0 mm. In addition, the width of the interconnector 16 may be set to be approximately the same as that of the busbar electrode.

The finger electrode 32, the busbar electrode 34A, and the busbar electrode 34B preferably include highly conductive metal. Examples of the highly conductive metal include gold, silver, copper, and the like. Silver, silver compounds, silver-containing alloys, and the like are preferred since the conductivity or the corrosion resistance is high. The conductive layer 36 preferably includes not only the highly conductive metal but also highly light-reflective components, for example, aluminum from the viewpoint of improving the photoelectric conversion efficiency of the solar cell element by reflecting light received on the light-receiving surface. The finger electrode 32, the busbar electrode 34A, the busbar electrode 34B, and the conductive layer 36 are formed by applying conductive material paint including the highly conductive metal onto the light-receiving surface 22A or the rear surface 22B of the solar cell element 13 by means of, for example, screen printing, then, drying the paint, and baking the paint as necessary.

Subsequently, a method for manufacturing the solar cell module 10 will be described. The method for manufacturing the solar cell module 10 includes (i) a step of forming a laminate by laminating the light-receiving surface-side protective member 14, the first solar cell-encapsulating material S1, the solar cell elements 13, the second solar cell-encapsulating material S2, and the rear surface-side protective member 15 in this order and (ii) a step of integrating the obtained laminate by means of pressurizing and heating or light irradiation.

In Step (i), in a case where the solar cell-encapsulating material S is embossed, a surface on which an uneven shape (embossed shape) is formed is preferably disposed so as to be on the solar cell element 13 side.

In Step (ii), the laminate obtained in Step (i) is heated and pressurized using a vacuum laminator or a heat press according to an ordinary method so as to be integrated (encapsulated). Alternatively, in Step (ii), the laminate obtained in Step (i) is irradiated with light such as ultraviolet rays so as to be photocross-linked and integrated (encapsulated).

During the encapsulating, the solar cell-encapsulating material S has high cushioning properties, and thus it is possible to prevent damage to the solar cell elements. In addition, the solar cell-encapsulating material has favorable deaeration properties, and thus air is not trapped, and it is possible to manufacture high-quality products with a favorable yield.

Hitherto, the embodiment of the present invention has been described with reference to the drawings, but the embodiment is simply an example of the present invention, and a variety of configurations other than what has been described above can also be employed.

### EXAMPLE

The present invention will be specifically described below based on examples. However, the present invention is not limited to the following examples.

(Method for Measuring Elastic Modulus of Solar Cell-Encapsulating Material Sheet)

In examples and comparative examples, the elastic modulus of a solar cell-encapsulating material configuring light-receiving surface side-encapsulating layers was measured as described below. A 1 mm-thick solar cell-encapsulating sheet having the same composition as the light-receiving surface side-encapsulating layers of the examples and the comparative examples was prepared. In addition, the elastic modulus of the sheet was measured on the basis of JIS K7161 using an autograph (manufactured by Shimadzu Corporation: AGS-J) under conditions of a distance between chucks of 40 mm and a tensile rate of 1 ram/min. In addition, the temperature of the measurement environment was set to 23° C. and 50% Rh.

### Example 1

1. Production of Solar Cell-Encapsulating Sheet

An ethylene.α-olefin copolymer 1 (α-olefin: 1-butene, the content proportion of an α-olefin unit: 14 mol %, the content proportion of an ethylene unit: 86 mol %, the Shore A hardness: 70, MFR: 4.0 g/10 minutes, and the density: 0.870 g/cm³) was synthesized using the same method as in Synthesis Example 1 of WO2012/060086. Next, 0.4 parts by mass of γ-methacryloxypropyl trimethoxysilane as a silane coupling agent, 0.8 parts by mass of t-butyl peroxy-2-ethylhexyl carbonate as a cross-linking agent, 1.2 parts by mass of triallyl isocyanurate as a cross-linking assistant, 0.4 parts by mass of 2-hydroxy-4-normal-octyloxy benzophenone as an ultraviolet absorbing agent, 0.2 parts by mass of bis(2,2,6,6-tetramethyl-4-piperidyl) sebacate as a light stabilizer, 0.1 parts by mass of tris(2,4-di-tert-butylphenyl)phosphite as a heat-resistance stabilizer 1, and 0.1 parts by mass of octadecyl-3-(3,5-di-tert-butyl-4-hydroxyphenyl)propionate as a heat-resistance stabilizer 2 were blended into 100 parts by mass of the ethylene.α-olefin copolymer, a resin composition was melt-extruded to a sheet shape using an extrusion molder under a condition of a dice temperature of 105° C., the sheet was cooled and solidified using a cooling roll and then wound, thereby producing a solar cell-encapsulating sheet. The elastic modulus at 23° C. of the obtained solar cell-encapsulating sheet was 10 MPa. In addition, the average thickness of the solar cell-encapsulating sheet was 0.60 mm.

2. Production of Solar Cell Module

Individual members used for a solar cell module are as described below.

As a light-receiving surface-side protective member, a white float glass plate (3.2 mm-thick emboss-attached thermally-treated glass) manufactured by AGC fabritech Co., Ltd. was used. The depth (Z) of a recess portion of the light-receiving surface-side protective member was 0.05 mm.

As a solar cell element, an element in which 18 cells having a 0.35 mm-thick busbar silver electrode in the center on the light-receiving surface side (single-crystal cells manufactured by Shinsung Solar Co., Ltd., 5 cm×3 cm) were connected to one another in series was used. Here, the respective cells were connected to one another in series using copper ribbon electrodes. The copper ribbon electrode was an electrode obtained by coating the surface of a copper foil with eutectic solder.

As a rear surface-side protective member, a silica-deposited PET-based backsheet was used.

As a solar cell rear surface-encapsulating material, the same solar cell-encapsulating sheet as for the light-receiving surface was used.

The solar cell module was produced in the following order.

First, the obtained solar cell-encapsulating sheet was set between the light-receiving surface-side protective member and the solar cell elements, and the solar cell rear surface-encapsulating material was set between the solar cell elements and the rear surface-side protective member, thereby obtaining a laminate. Next, an approximately 2 cm-long notch was made in a portion of the rear surface-side protective member, and a positive terminal and a negative terminal were removed from the solar cell element. Next, the obtained laminate was vacuum-laminated using a vacuum laminator (LM-110×160-S manufactured by Seiko NPC Corporation) under at a hot plate temperature of 150° C. for a vacuum time of three minutes and a pressurization time of 15 minutes. Here, the layer formed of the solar cell-encapsulating sheet is the light-receiving surface side-encapsulating layer. In addition, the average thickness of the light-receiving surface side-encapsulating layer was 0.60 mm.

Next, the light-receiving surface side-encapsulating layer extracted from the light-receiving surface-side protective member and the rear surface-side protective member were cut, and an end surface-encapsulating sheet was imparted to an end portion of the light-receiving surface-side protective member, thereby attaching an aluminum frame thereto. Next, RTV silicone was imparted to the notch portion of the terminal portion extracted from the rear surface-side protective member and was cured. A solar cell module was obtained using the above-described method. Here, the average thickness of the light-receiving surface side-encapsulating layer formed using the solar cell-encapsulating sheet was 0.60 mm.

3. Evaluation of Solar Cell Module

On the obtained solar cell module, 200 cycles of a temperature cycle test was performed using a temperature cycle tester (PSL-2J manufactured by ESPEC Corp.) on the basis of JIS C8917. The IV characteristics of the solar cell module before and after 200 cycles were respectively evaluated using a xenon light source having an air mass (AM) 1.5-class A light intensity distribution. In the IV evaluation, PVS-116i-S manufactured by Nisshinbo Mechatronics Inc. was used. The evaluation results were classified as described below. The results are shown in Table 1. Meanwhile, the output maintenance ratio means 100×(the output of the solar cell module after 200 cycles of the temperature cycle test)/(the output of the solar cell module before the temperature cycle test).

The output maintenance ratio is equal to or greater than 95%: A

The output maintenance ratio is equal to or greater than 90% and less than 95%: B

The output maintenance ratio is smaller than 90%: C

### Examples 2 and 3, Comparative Example 1, and Reference Example 1

Solar cell modules were respectively produced in the same manner as in Example 1 except for the fact that the average thicknesses (X) of light-receiving surface side-encapsulating layers were set to values shown in Table 1 by changing the average thicknesses of solar cell encapsulating sheets, and the output maintenance ratios were respectively measured. The results are shown in Table 1.

### Example 4

A solar cell-encapsulating sheet was produced in the same manner as in Example 2 except for the fact that a resin composition obtained by adding 20 parts by mass of LUCANT HC-40 manufactured by Mitsui Chemicals, Inc., which was a lubricant, in order to adjust the elastic modulus to, instead of the ethylene.α-olefin copolymer 1, 80 parts by mass of an ethylene.α-olefin copolymer 1 (α-olefin: 1-butene, the content proportion of an α-olefin unit: 14 mol %, the content proportion of an ethylene unit: 86 mol %, the Shore A hardness: 70, MFR: 4.0 g/10 minutes, and the density: 0.870 g/cm³) was used. The elastic modulus at 23° C. of the obtained solar cell-encapsulating sheet was 6 MPa. In addition, a solar cell module was produced in the same manner as in Example 1, and the output maintenance ratio was measured. The results are shown in Table 1.

### Example 5

A solar cell-encapsulating sheet was produced in the same manner as in Example 2 except for the fact that an ethylene.α-olefin copolymer 2 (α-olefin: 1-octene, the content proportion of an α-olefin unit: 11 mol %, the content proportion of an ethylene unit: 89 mol %, the Shore A hardness: 84, MFR: 48 g/10 minutes, and the density: 0.884 g/cm³), which was synthesized using the same method as in Synthesis Example 3 of WO2012/046456, was used instead of the ethylene.α-olefin copolymer 1. The elastic modulus at 23° C. of the obtained solar cell-encapsulating sheet was 28 MPa. In addition, a solar cell module was produced in the same manner as in Example 1, and the output maintenance ratio was measured. The results are shown in Table 1.

### Comparative Example 2

A solar cell-encapsulating sheet was produced in the same manner as in Example 2 except for the fact that a resin composition obtained by adding 20 parts by mass of LUCANT HC-40 manufactured by Mitsui Chemicals, Inc., which was a lubricant, in order to adjust the elastic modulus to, instead of the ethylene.α-olefin copolymer 1, 80 parts by mass of an ethylene.α-olefin copolymer 3 (α-olefin: 1-butene, the content proportion of an α-olefin unit: 18 mol %, the content proportion of an ethylene unit: 82 mol %, the Shore A hardness: 60, MFR: 9.5 g/10 minutes, and the density: 0.865 g/cm³), which was synthesized using the same method as in Synthesis Example 2 of WO2012/060086, was used. The elastic modulus at 23° C. of the obtained solar cell-encapsulating sheet was 4 MPa. In addition, a solar cell module was produced in the same manner as in Example 1, and the output maintenance ratio was measured. The results are shown in Table 1.

### Comparative Example 3

A solar cell-encapsulating sheet was produced in the same manner as in Example 2 except for the fact that an ethylene.α-olefin copolymer 4 (α-olefin: 1-butene, the content proportion of an α-olefin unit: 11 mol %, the content proportion of an ethylene unit: 89 mol %, the Shore A hardness: 86, MFR: 4.0 g/10 minutes, and the density: 0.885 g/cm³), which was synthesized using the same method as in Synthesis Example 7 of WO2012/060086, was used instead of the ethylene.α-olefin copolymer 1. The elastic modulus at 23° C. of the obtained solar cell-encapsulating sheet was 32 MPa. In addition, a solar cell module was produced in the same manner as in Example 1, and the output maintenance ratio was measured. The results are shown in Table 1.

Meanwhile, in the examples and the comparative examples, methods for measuring the thicknesses and the like of the respective members were performed on the basis of the following methods.

1. Average Thickness (X) of Light-Receiving Surface Side-Encapsulating Layer

The average thickness of the light-receiving surface side-encapsulating layer was computed from X=W₁/(D₁×10) using the weight W₁ (g/100 cm²) of a 10 cm×10 cm-sized specimen of the light-receiving surface side-encapsulating layer and the density D₁ (g/cm³) of the light-receiving surface side-encapsulating layer.

Here, the density D₁ of the light-receiving surface side-encapsulating layer was measured on the basis of ASTM D1505.

2. Average thickness (Y) of Busbar Electrode and Average Thickness of Semiconductor Element

The average thickness (Y) of the busbar electrode and the average thickness of the semiconductor element were computed from photographs captured using a scanning electron microscope. Specifically, the cross-sections of the busbar electrode and the semiconductor element were captured, ten portions were arbitrarily selected from the obtained photographs, and the thicknesses of the busbar electrode and the semiconductor element at those portions were respectively measured. In addition, a value obtained by integrating all of the thicknesses of the busbar electrode and then dividing the sum by 10 was considered as the average thickness (Y) of the busbar electrode, and a value obtained by integrating all of the thicknesses of the semiconductor element and then dividing the sum by 10 was considered as the average thickness of the semiconductor element.

3. Depth (Z) of Recess Portion of Light-Receiving Surface-Side Protective Member

First, the basis thickness Z₁=W₂/(D₂×10) was computed using the weight W₂ (g/100 cm²) of a 10 cm×10 cm-sized specimen of the light-receiving surface-side protective member and the density D₂ (g/cm³) of the light-receiving surface-side protective member.

Next, the apparent thickness Z₂ [mm] of the light-receiving surface-side protective member was measured at the protrusion portion using a dial gauge (MODEL H manufactured by Peacock Ozaki Mfg. Co., Ltd.). Here, the apparent thickness Z₂ of the light-receiving surface-side protective member was the average value of thicknesses measured at ten protrusion portions of the light-receiving surface-side protective member.

In addition, the depth (Z) of the recess portion was computed from Z=Z₂−Z₁.

Here, the density D₁ of the light-receiving surface side-protective member was measured on the basis of ASTM D1505.

TABLE 1

| | | Example | Example | Example | Example | Example | Comparative | Comparative | Comparative | Reference |
|---|---|---|---|---|---|---|---|---|---|---|
| | | 1 | 2 | 3 | 4 | 5 | Example 1 | Example 2 | Example 3 | Example 1 |
| Resin (P) | Ethylene•α-olefin | 100 | 100 | 100 | 80 | | 100 | | | 100 |
| | copolymer 1 | | | | | | | | | |
| | Ethylene•α-olefin | | | | | 100 | | | | |
| | copolymer 2 | | | | | | | | | |
| | Ethylene•α-olefin | | | | | | | 80 | | |
| | copolymer 3 | | | | | | | | | |
| | Ethylene•α-olefin | | | | | | | | 100 | |
| | copolymer 4 | | | | | | | | | |

| | | | | | | | | | |
|---|---|---|---|---|---|---|---|---|---|
| Lubricant | | | | 20 | | | 20 | | |
| Elastic modulus of solar | 10 | 10 | 10 | 6 | 28 | 10 | 4 | 32 | 10 |
| cell-encapsulating material | | | | | | | | | |
| configuring light-receiving | | | | | | | | | |
| surface side-encapsulating | | | | | | | | | |
| layer [MPa] | | | | | | | | | |
| Average thickness of | 0.60 | 0.45 | 0.50 | 0.45 | 0.45 | 0.40 | 0.45 | 0.45 | 0.70 |
| light-receiving surface | | | | | | | | | |
| side-encapsulating layer (X) [mm] | | | | | | | | | |
| Average thickness of busbar | 0.35 | 0.35 | 0.35 | 0.35 | 0.35 | 0.35 | 0.35 | 0.35 | 0.35 |
| electrode (Y) [mm] | | | | | | | | | |
| Depth of recess portion of | 0.05 | 0.05 | 0.05 | 0.05 | 0.05 | 0.05 | 0.05 | 0.05 | 0.05 |
| light-receiving | | | | | | | | | |
| surface-side protective | | | | | | | | | |
| member (Z) [mm] | | | | | | | | | |
| Effective thickness of | 0.20 | 0.05 | 0.10 | 0.05 | 0.05 | 0.00 | 0.05 | 0.05 | 0.30 |
| light-receiving surface | | | | | | | | | |
| side-encapsulating layer | | | | | | | | | |
| represented by (X − Y − Z) [mm] | | | | | | | | | |
| Output maintenance ratio | A | A | A | A | A | C | C | C | A |

It could be confirmed that the output maintenance ratios of the solar cell modules of Examples 1 to 5 were equal to or greater than 95% respectively and the output reduction of the solar cell modules was suppressed. In contrast, it could be confirmed that the output maintenance ratios of the solar cell modules of Comparative Examples 1 to 3 were smaller than 90% respectively and significant output reduction of the solar cell modules was caused.

In addition, even from the comparison with the solar cell module of the reference example in which the effective thickness was 0.30 mm, it is found that the solar cell modules of Examples 1 to 5 had a sufficient output reduction prevention function. That is, it could be confirmed that, in Examples 1 to 5, the output reduction was suppressed, and the solar cell modules in which the thickness of the encapsulating layer was thin could be realized.

This application is based upon and claims the benefit of priority from Japanese Patent Application No. 2015-229758; filed on Nov. 25, 2015; the entire contents of which are incorporated herein by reference.

1. A solar cell module comprising:
a light-receiving surface-side protective member;
a rear surface-side protective member;
a solar cell element; and
an encapsulating layer that encapsulates the solar cell element between the light-receiving surface-side protective member and the rear surface-side protective member,
wherein the light-receiving surface-side protective member has a plurality of fine recess portions and a plurality of fine protrusion portions on at least the solar cell element-side surface,
a busbar electrode is provided to the solar cell element on at least a light-receiving surface-side surface,
the encapsulating layer has a light-receiving surface side-encapsulating layer provided between the light-receiving surface-side protective member and the solar cell element and a rear surface-side encapsulating layer provided between the rear surface-side protective member and the solar cell element, the solar cell element is encapsulated between the light-receiving surface side-encapsulating layer and the rear surface-side encapsulating layer,
the light-receiving surface side-encapsulating layer includes at least one type of resin selected from a polyolefin-based resin and an ethylene.polar monomer copolymer,
an elastic modulus at 23° C. of a solar cell-encapsulating material configuring the light-receiving surface side-encapsulating layer is equal to or greater than 5 MPa and equal to or smaller than 30 MPa, and
when an average thickness of the light-receiving surface side-encapsulating layer is represented by X [mm], an average thickness of the busbar electrode on the light-receiving surface side is represented by Y [mm], and a depth of the recess portion is represented by Z [mm], an effective thickness of the light-receiving surface side-encapsulating layer represented by (X-Y-Z) is equal to or greater than 0.01 mm and smaller than 0.25 mm.

2. The solar cell module according to claim 1,
wherein the average thickness (Y) of the busbar electrode is equal to or greater than 0.02 mm and equal to or smaller than 0.6 mm.

3. The solar cell module according to claim 1,
wherein the depth (Z) of the recess portion is equal to or greater than 0.02 mm and equal to or smaller than 0.5 mm.

4. The solar cell module according to claim 1,
wherein the resin included in the light-receiving surface side-encapsulating layer includes an ethylene.α-olefin copolymer.

5. The solar cell module according to claim 1,
wherein the average thickness of the solar cell element is equal to or greater than 0.01 mm and equal to or smaller than 0.5 mm.

6. The solar cell module according to claim 1,
wherein the average thickness (X) of the light-receiving surface side-encapsulating layer is equal to or smaller than 0.60 mm.

7. The solar cell module according to claim 1,
wherein the solar cell-encapsulating material configuring the light-receiving surface side-encapsulating layer further includes a lubricant.
